(19) United States
(12) Patent Application Publication
(10) Pub. No.: US 2009/0121904 A1
(43) Pub. Date: May 14, 2009

(54) LIGHT-EMITTING KEYBOARD

(75) Inventors: CHANG-CHUN LIU, Shenzhen (CN); XIAO-LIN GAN, Shenzhen (CN); YU-KUANG HO, Tu-Cheng (TW)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/965,749

(22) Filed: Dec. 28, 2007

(30) Foreign Application Priority Data
Nov. 8, 2007 (CN) 200710202418.0

(51) Int. Cl. H03K 17/94; F21V 33/00

(52) U.S. Cl. 341/22; 362/253

(57) ABSTRACT

A light-emitting keyboard includes an upper cover with a plurality of keystrokes, the keystrokes being made of transparent material, a printed circuit board (PCB) connected to a connector via a cable, a lower cover, a light guide plate and a diffusion plate arranged in sequence between the upper cover and the lower cover, and a light source arranged beside the light guide plate and connected to the PCB to receive power. Thus, the light-emitting keyboard can be used in a dark or gloomy environment.

### CROSS-REFERENCES TO RELATED APPLICATION

Relevant subject matter is disclosed in co-pending U.S. patent application entitled “LIGHT-EMITTING KEYBOARD”, filed on Nov. 29, 2007 with application Ser. No. 11/946,863, and assigned to the same assignee as this application.

### BACKGROUND OF THE INVENTION

1. Field of the Invention

The present invention relates to keyboards, and particularly to a light-emitting keyboard.

2. Description of Related Art

A computer system includes many components, such as the central processing unit (or processor), temporary memory for storing program instructions (like random access memory, or RAM), a permanent storage device (such as a hard disk), and a variety of user interface devices, such as a video display, a keyboard, and a pointing device.

Referring to FIG. 4, a conventional keyboard includes an upper cover 12 with a plurality of keystrokes 122, a rubber layer 14, a partitioning layer 16, a printed circuit board (PCB) 17 connected to the partitioning layer 16, and a lower cover 18. The PCB 17 is connected to a connector 174 via a cable 172 for coupling the keyboard to the computer system via the connector 174.

Keyboards are used in a variety of applications for entry of alphanumeric and other types of data into a computer system. But it is hard to use a keyboard in a dark or gloomy environment.

What is needed, therefore, is a light-emitting keyboard which can solve the above problem.

### SUMMARY

An exemplary light-emitting keyboard includes an upper cover with a plurality of keystrokes, the keystrokes being made of transparent material, a printed circuit board (PCB) connected to a connector via a cable, a lower cover, a light guide plate, and a diffusion plate arranged in sequence between the upper cover and the lower cover, and a light source arranged beside the light guide plate and connected to the PCB to receive power. Thus, the light-emitting keyboard can be used in a dark or gloomy environment.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an exploded view of a light-emitting keyboard in accordance with the present invention;

FIG. 2 is a cross-sectional view of an assembly of FIG. 1;

FIG. 3 is a circuit diagram of an electroluminescent linear light source and a power adapter of FIG. 1; and

FIG. 4 is an exploded, isometric view of a conventional keyboard.

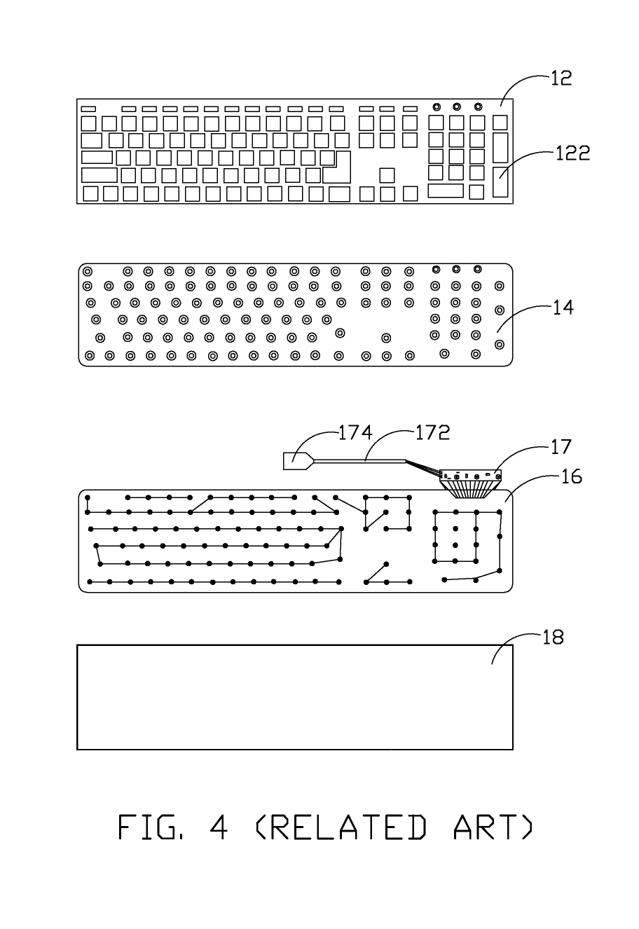

### DETAILED DESCRIPTION

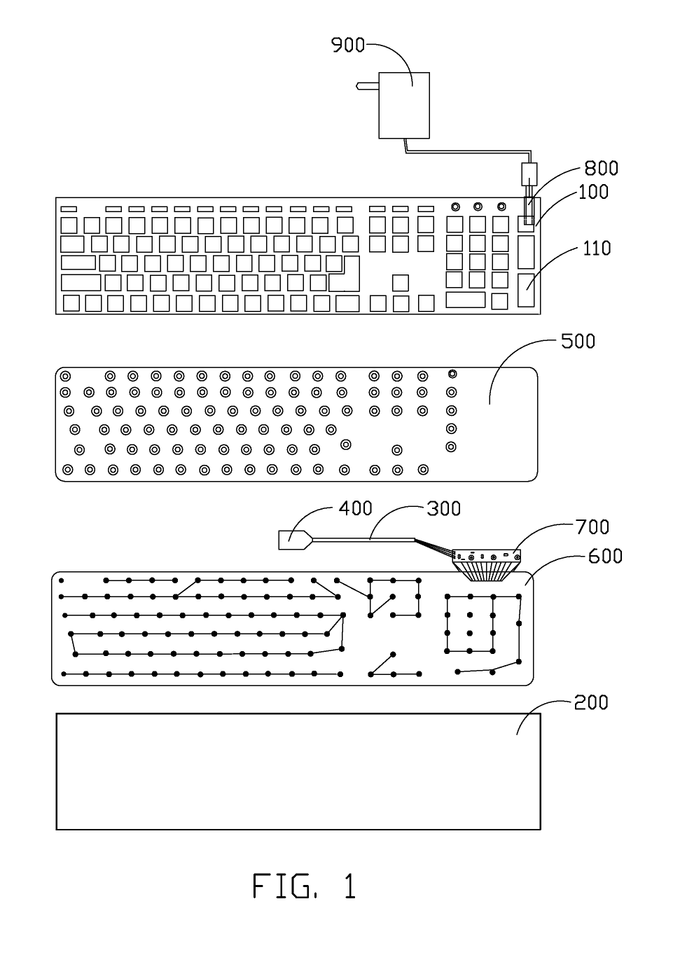

Referring to FIG. 1, a light-emitting keyboard in accordance with an embodiment of the present invention includes an upper cover 100 with a plurality of keystrokes 110, a lower cover 200, a connector 400, a rubber layer 500, a partitioning layer 600, a printed circuit board 700, a power plug 800, a power adapter 900, and a light-emitting module. The printed circuit board 700 is connected to the connector 400 via a cable 300. The rubber layer 500, the partitioning layer 600, and the light-emitting module are located in sequence between the upper cover 100 and the lower cover 200. The partitioning layer 600 is electrically connected to the printed circuit board 700. The power adapter 900 supplies power to the light-emitting module via the power plug 800.

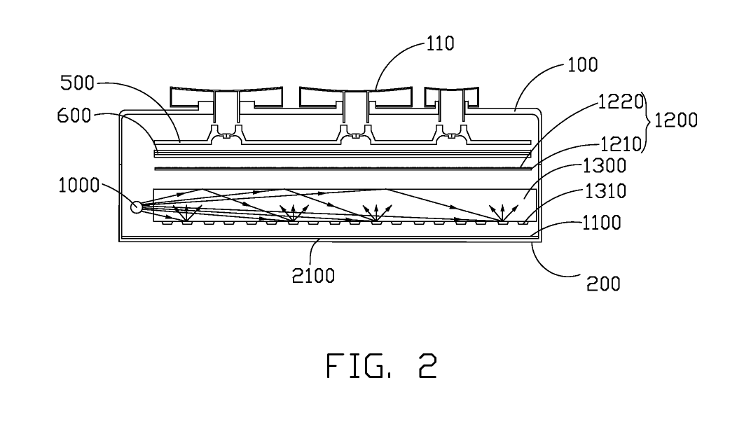

Referring to FIG. 2, the light-emitting module includes an electro-luminescent (EL) source 1000, an inverter 1100, a diffusion plate 1200, and a guiding plate 1300. The EL source 1000 is located beside the guiding plate 1300. The inverter 1100 is located on the lower cover 200. The diffusion plate 1200 and the guiding plate 1300 are located in sequence between the partitioning layer 600 and the lower cover 200. The guiding plate 1300 includes a bottom surface on which a plurality of preferably round identical protrusions 1310 is formed to enhance the reflectivity of light from the light-emitting module. The diffusion plate 1200 includes a base plate 1210 and a smooth plate 1220. The base plate 1210 is configured to support the smooth plate 1220. The smooth plate 1220 is configured to diffuse light from the EL source 1000. At the inner bottom of the lower cover 200, there is a reflection layer 2100 configured for reflecting light from the EL source 1000 to the guiding plate 1300.

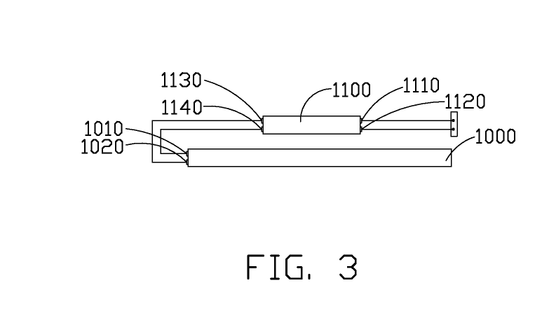

Referring to FIG. 3, the EL source 1000 includes two terminals 1010 and 1020. The inverter 1100 includes two input terminals 1110, 1120, and two output terminals 1130, 1140. The two terminals 1010 and 1020 are connected to the two output terminals 1130 and 1140 of the inverter 1100 respectively. The two input terminals 1110 and 1120 of the inverter 1100 are connected to the power adapter 900.

The EL source 1000 receives power from the power adapter 900 via the inverter 1100, or directly from the computer system. Thus, the light-emitting keyboard can be used in a dark or gloomy environment.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A light-emitting keyboard comprising:
an upper cover with a plurality of keystrokes, the keystrokes being made of transparent material;
a printed circuit board (PCB) connected to a connector via a cable;
a lower cover;
a light guide plate and a diffusion plate arranged in sequence between the upper cover and the lower cover; and
a light source arranged beside the light guide plate and connected to the PCB to receive power.

2. The light-emitting keyboard as claimed in claim 1, wherein the light source is an electro-luminescent source.

3. The light-emitting keyboard as claimed in claim 2, further comprising: an inverter electrically connected to the electro-luminescent source, and a power plug electrically connected to the inverter.

4. The light-emitting keyboard as claimed in claim 1, wherein the diffusion plate includes a base plate and a smooth plate, the base plate is configured to support the smooth plate, the smooth plate is configured to diffuse light from the light-emitting module.

5. The light-emitting keyboard as claimed in claim 1, further comprising: a reflection layer at the inner bottom of the lower cover, the reflection layer configured for reflecting light from the light source to the guiding plate.

6. A light-emitting keyboard comprising:
an upper cover with a plurality of keystrokes, the keystrokes being made of transparent material;
a printed circuit board (PCB) connected to a connector via a cable;
a lower cover;
a light guide plate and a diffusion plate arranged in sequence between the upper cover and the lower cover;
a light source arranged beside the light guide plate and connected to a power plug via an inverter; and
a power adapter connected to the power plug to supply power to the light source.

7. The light-emitting keyboard as claimed in claim 7, wherein the light source is an electro-luminescent source.

8. The light-emitting keyboard as claimed in claim 7, wherein the diffusion plate includes a base plate and a smooth plate, the base plate is configured to support the smooth plate, the smooth plate is configured to diffuse light from the light-emitting module.

9. The light-emitting keyboard as claimed in claim 7, further comprising: a reflection layer at the inner bottom of the lower cover, the reflection layer is configured for reflecting light from the light source to the guiding plate.
